(19) United States
(12) Patent Application Publication
(10) Pub. No.: US 2026/0173311 A1
(43) Pub. Date: Jun. 18, 2026

(54) VERTICALLY MOUNTED SIDE-BY-SIDE LIQUID COOLING LEAK SEGREGATION SYSTEM

(71) Applicant: Dell Products L.P., Round Rock, TX (US)

(72) Inventors: Per Henrik Fremrot, Novato, CA (US); Colin Montgomery, Mountain View, CA (US)

(21) Appl. No.: 18/983,568

(22) Filed: Dec. 17, 2024

(51) Int. Cl. H05K 7/20

(52) U.S. Cl. CPC H05K 7/20272; H05K 7/20781

(57) ABSTRACT

A vertically-mounted side-by-side liquid cooling leak segregation system includes a rack defining a first vertical liquid cooling device housing that is located immediately adjacent a first vertical computing device housing. A first computing device is located in the first vertical computing device housing. A first liquid cooling device is located in the first vertical liquid cooling device housing and thermally engages the first computing device to dissipate heat generated by the first computing device. The first vertical computing device housing and the first vertical liquid cooling device housing position the first computing device side-by-side with the first liquid cooling device to prevent, in response to a first liquid that is circulated through the first liquid cooling device leaking from the first liquid cooling device, the first liquid leaking from the first liquid cooling device from entering the first vertical computing device housing and engaging the first computing device.

### BACKGROUND

The present disclosure relates generally to information handling systems, and more particularly to vertically mounting liquid cooling devices in a rack side-by-side with information handling systems they are used to cool in order to segregate any leaks that might occur in those liquid cooling devices.

As the value and use of information continues to increase, individuals and businesses seek additional ways to process and store information. One option available to users is information handling systems. An information handling system generally processes, compiles, stores, and/or communicates information or data for business, personal, or other purposes thereby allowing users to take advantage of the value of the information. Because technology and information handling needs and requirements vary between different users or applications, information handling systems may also vary regarding what information is handled, how the information is handled, how much information is processed, stored, or communicated, and how quickly and efficiently the information may be processed, stored, or communicated. The variations in information handling systems allow for information handling systems to be general or configured for a specific user or specific use such as financial transaction processing, airline reservations, enterprise data storage, or global communications. In addition, information handling systems may include a variety of hardware and software components that may be configured to process, store, and communicate information and may include one or more computer systems, data storage systems, and networking systems.

Information handling systems such as, for example, server devices, networking devices (e.g., switch devices), storage systems, and/or other computing devices known in the art, are often provided in racks that are configured to house a plurality of computing devices. As will be appreciated by one of skill in the art in possession of the present disclosure, the functionality provided by those computing devices is often limited by the ability to dissipate the heat generated by the processing components in those computing devices, and requires the provisioning of air cooling systems (e.g., fans, faceplates with airflow apertures, internal airflow volumes, airflow channeling components, etc.) that allow air to flow through the computing devices and over their processing components in order to dissipate that heat, but that also utilize valuable space in the rack.

Liquid cooling systems offer the ability to cool computing devices in a rack while utilizing substantially less space in the rack than the air cooling systems discussed above by positioning liquid cooling devices on top of and in contact with computing devices in the rack, and then circulating a liquid through those liquid cooling devices to dissipate the heat generated by the computing devices. However, reliability issues with liquid cooling systems have limited or prevented their use in racks, as the potential of leaks occurring with such liquid cooling systems that would expose relatively expensive computing devices to the liquid used to cool them often presents too much of a risk. While some racks utilize hybrid air/liquid cooling systems, one of skill in the art in possession of the present disclosure will recognize how the combination of the air cooling systems and liquid cooling systems discussed above still presents the rack space utilization and reliability issues described above. While immersion cooling systems that submerge the rack and its computing devices in a dielectric fluid provide another cooling option, such immersion cooling systems have uncertain/unproven reliability and generally present a wide variety of implementation and utilization issues.

Accordingly, it would be desirable to provide a rack-based computing device cooling system that addresses the issues discussed above.

### SUMMARY

According to one embodiment, a vertically-mounted side-by-side liquid cooling leak segregation system includes a rack; a plurality of vertical liquid cooling device housings that are defined by the rack and that are each configured to house a respective liquid cooling device; and a plurality of vertical computing device housings that are defined by the rack such that a respective one of the plurality of vertical computing device housings is located immediately adjacent a respective one of the plurality of vertical liquid cooling device housings, wherein each of the plurality of vertical computing device housings is configured to house a respective computing device, and wherein the plurality of vertical liquid cooling device housings and the plurality of vertical computing device housings are configured to position the respective computing device housed in any of the plurality of vertical computing device housings side-by-side and in thermal engagement with the respective liquid cooling device housed in one of the plurality of vertical liquid cooling device housings that is located immediately adjacent that vertical computing device housing to prevent, in response to a liquid that is circulated through that respective liquid cooling device leaking from that respective liquid cooling device, the liquid leaking from that respective liquid cooling device from entering that vertical computing device housing and engaging that respective computing device.

### BRIEF DESCRIPTION OF THE DRAWINGS

FIG. 1 is a schematic view illustrating an embodiment of an Information Handling System (IHS).

FIG. 2 is a front schematic view illustrating an embodiment of a rack that may be included in the vertically-mounted side-by-side liquid cooling leak segregation system of the present disclosure.

FIG. 3A is a perspective view illustrating an embodiment of a liquid cooling device that may be included in the vertically-mounted side-by-side liquid cooling leak segregation system of the present disclosure.

FIG. 3B is a perspective view illustrating an embodiment of the liquid cooling device of FIG. 3A including a computing device coupling subsystem.

FIG. 3C is a perspective view illustrating an embodiment of the liquid cooling device of FIG. 3B including a computing device connector subsystem.

FIG. 4A is a perspective view illustrating an embodiment of a computing device that may be included in the vertically-mounted side-by-side liquid cooling leak segregation system of the present disclosure.

FIG. 4B is a perspective view illustrating an embodiment of the computing device of FIG. 4A including a plurality of heat sink devices.

FIG. 4C is a rear view illustrating an embodiment of the computing device of FIG. 4B.

FIG. 5 is a flow chart illustrating an embodiment of a method for vertically mounting liquid cooling devices side-by-side in a rack with computing devices to segregate leaks.

FIG. 6A is a front schematic view illustrating an embodiment of the liquid cooling device of FIG. 3C coupled to the rack of FIG. 2 during the method of FIG. 5.

FIG. 6B is a front schematic view illustrating an embodiment of a pair of the computing devices of FIG. 4C coupled to the liquid cooling device in the rack of FIG. 6A during the method of FIG. 5.

FIG. 6C is a perspective view illustrating an embodiment of a pair of the computing devices coupled to the liquid cooling device in FIG. 6B during the method of FIG. 5.

FIG. 6D is a rear schematic view illustrating an embodiment of one of the pair of the computing devices coupled to the liquid cooling device in FIG. 6C during the method of FIG. 5.

FIG. 7A is a perspective view illustrating an embodiment of pairs of the computing devices of FIG. 4C coupled to a plurality of the liquid cooling devices of FIG. 3C in the rack of FIG. 2 during the method of FIG. 5.

FIG. 7B is a front schematic view illustrating an embodiment of pairs of the computing devices coupled to a plurality of the liquid cooling devices in the rack in FIG. 7A during the method of FIG. 5.

FIG. 7C is a rear schematic view illustrating an embodiment of one of the computing devices coupled to a pair of the liquid cooling devices in FIGS. 7A and 7B during the method of Fig.

FIG. 8 is a front schematic view illustrating an embodiment of the computing devices and the liquid cooling devices in the rack in FIG. 7B operating during the method of FIG. 5.

FIG. 9 is a front schematic view illustrating an embodiment of one of the liquid cooling devices in the rack in FIG. 7B operating during the method of FIG. 5.

### DETAILED DESCRIPTION

For purposes of this disclosure, an information handling system may include any instrumentality or aggregate of instrumentalities operable to compute, calculate, determine, classify, process, transmit, receive, retrieve, originate, switch, store, display, communicate, manifest, detect, record, reproduce, handle, or utilize any form of information, intelligence, or data for business, scientific, control, or other purposes. For example, an information handling system may be a personal computer (e.g., desktop or laptop), tablet computer, mobile device (e.g., personal digital assistant (PDA) or smart phone), server (e.g., blade server or rack server), a network storage device, or any other suitable device and may vary in size, shape, performance, functionality, and price. The information handling system may include random access memory (RAM), one or more processing resources such as a central processing unit (CPU) or hardware or software control logic, ROM, and/or other types of nonvolatile memory. Additional components of the information handling system may include one or more disk drives, one or more network ports for communicating with external devices as well as various input and output (I/O) devices, such as a keyboard, a mouse, touchscreen and/or a video display. The information handling system may also include one or more buses operable to transmit communications between the various hardware components.

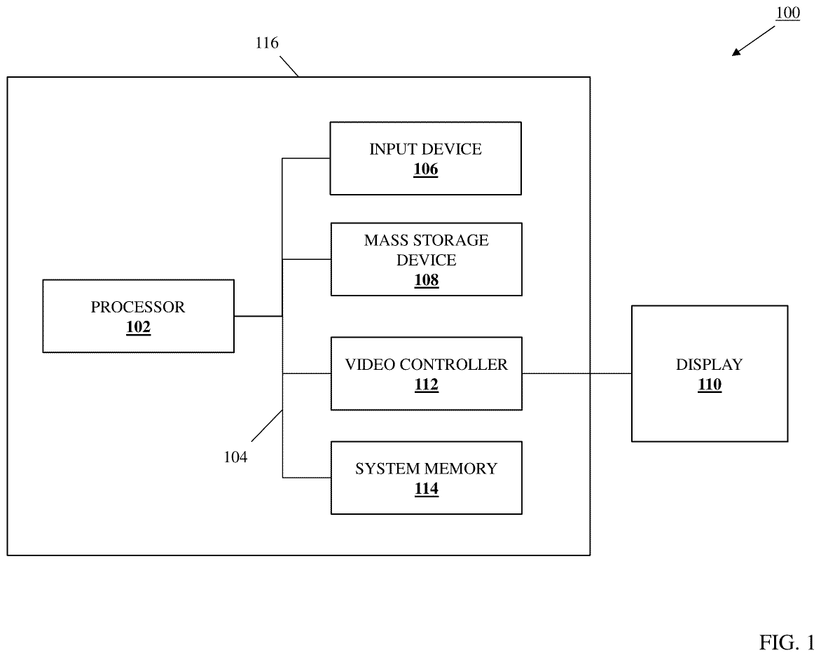

In one embodiment, IHS 100, FIG. 1, includes a processor 102, which is connected to a bus 104. Bus 104 serves as a connection between processor 102 and other components of IHS 100. An input device 106 is coupled to processor 102 to provide input to processor 102. Examples of input devices may include keyboards, touchscreens, pointing devices such as mouses, trackballs, and trackpads, and/or a variety of other input devices known in the art. Programs and data are stored on a mass storage device 108, which is coupled to processor 102. Examples of mass storage devices may include hard discs, optical disks, magneto-optical discs, solid-state storage devices, and/or a variety of other mass storage devices known in the art. IHS 100 further includes a display 110, which is coupled to processor 102 by a video controller 112. A system memory 114 is coupled to processor 102 to provide the processor with fast storage to facilitate execution of computer programs by processor 102. Examples of system memory may include random access memory (RAM) devices such as dynamic RAM (DRAM), synchronous DRAM (SDRAM), solid state memory devices, and/or a variety of other memory devices known in the art. In an embodiment, a chassis 116 houses some or all of the components of IHS 100. It should be understood that other buses and intermediate circuits can be deployed between the components described above and processor 102 to facilitate interconnection between the components and the processor 102.

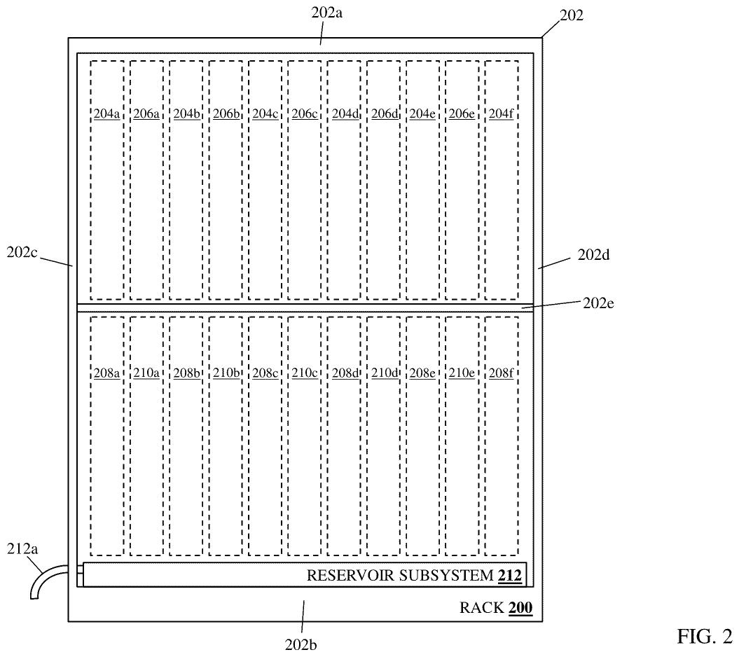

Referring now to FIG. 2, an embodiment of a rack 200 is illustrated that may be included in the vertically-mounted side-by-side liquid cooling leak segregation system of the present disclosure. In the illustrated embodiment, the rack 200 includes a chassis 200 having a top wall 202a, a bottom wall 202b that is located opposite the chassis 202 from the top wall 202a, a pair of opposing side walls 202c and 202d that are located opposite the chassis 202 from each other and that extend between the top wall 202a and the bottom wall 202b, and an interior wall 202e that extends between the side walls 202c and 202d approximately midway between the top wall 202a and the bottom wall 202b. However, while the rack 200 is illustrated and described as including the interior wall 202e, one of skill in the art in possession of the present disclosure will recognize that the interior wall 202e may be omitted while providing the same functionality described below.

In the illustrated embodiment, the chassis 202 defines a plurality of vertical liquid cooling device housings 204a, 204b, 204c, 204d, 204e, and 204f between the top wall 202a, the intermediate wall 202e, and the side walls 202c and 202d. Furthermore, the chassis 202 also defines a plurality of vertical computing device housings 206a, 206b, 206c, 206d, and 206e between the top wall 202a, the intermediate wall 202e, and the side walls 202c and 202d, with each vertical computing device housing 206a-206e positioned between a pair of the vertical liquid cooling device housings 204a-204f (i.e., with the vertical computing device housing 206a positioned between the vertical liquid cooling device housings 204a and 204b, the vertical computing device housing 206b positioned between the vertical liquid cooling device housings 204b and 204c, the vertical computing device housing 206c positioned between the vertical liquid cooling device housings 204c and 204d, the vertical computing device housing 206d positioned between the vertical liquid cooling device housings 204d and 204e, and the vertical computing device housing 206e positioned between the vertical liquid cooling device housings 204e and 204f in FIG. 2).

As described below, each the vertical liquid cooling device housings 204a-204f is configured to house a liquid cooling device, and thus the top wall 202a and the intermediate wall 202e (and in some cases the side walls 202c and 202d) may include any of a variety of liquid cooling device coupling features, securing features, and/or other features that enable the vertical liquid cooling device housings 204a-204f to house those liquid cooling devices and/or otherwise provide the functionality described below.

In the illustrated embodiment, the chassis 202 also defines a plurality of vertical liquid cooling device housings 208a, 208b, 208c, 208d, 208e, and 208f between the top wall 202a, the intermediate wall 202e, and the side walls 202c and 202d. Furthermore, the chassis 202 also defines a plurality of vertical computing device housings 210a, 210b, 210c, 210d, and 210e between the top wall 202a, the intermediate wall 202e, and the side walls 202c and 202d, with each vertical computing device housing 210a-210e positioned between a pair of the vertical liquid cooling device housings 208a-208f (i.e., with the vertical computing device housing 210a positioned between the vertical liquid cooling device housings 208a and 208b, the vertical computing device housing 210b positioned between the vertical liquid cooling device housings 208b and 208c, the vertical computing device housing 210c positioned between the vertical liquid cooling device housings 208c and 208d, the vertical computing device housing 210d positioned between the vertical liquid cooling device housings 208d and 208e, and the vertical computing device housing 210e positioned between the vertical liquid cooling device housings 208e and 208f in FIG. 2).

As described below, each the vertical liquid cooling device housings 208a-208f is configured to house a liquid cooling device, and thus the top wall 202a and the intermediate wall 202e (and in some cases the side walls 202c and 202d) may include any of a variety of liquid cooling device coupling features, securing features, and/or other features that enable the vertical liquid cooling device housings 208a-208f to house those liquid cooling devices and/or otherwise provide the functionality described below.

As will be appreciated by one of skill in the art in possession of the present disclosure, the rack 200 illustrated and described below provides examples of a “full size” rack that includes vertical liquid cooling device housings that are configured to house modular “half-rack-height” liquid cooling devices for use in cooling computing devices, which allows a “half size” rack to utilize those modular “half-rack-height” liquid cooling devices for cooling half as many computing devices as the “full size” rack described below. However, while a specific rack configuration is illustrated and described herein, one of skill in the art in possession of the present disclosure will appreciate how the teachings of the present disclosure may be utilized in any of a variety of rack configurations while remaining within the scope of the present disclosure as well.

In the illustrated embodiment, a reservoir subsystem 212 is provided on the bottom wall 202b of the chassis 202 and opposite the vertical liquid cooling device housings 208a-208f and the vertical computing device housings 210a-210e from the intermediate wall 202e. As will be appreciated by one of skill in the art in possession of the present disclosure, the reservoir subsystem 212 may include any of a variety structures that are configured to hold a volume of liquid, and in the illustrated embodiment includes an emergency drain element 212a that is configured to allow liquid that reaches a maximum level in the reservoir subsystem 212 to be drained away from the chassis 212. As such, one of skill in the art in possession of the present disclosure will appreciate how the emergency drain element 212a may be coupled to a plumbing system in a datacenter in which the rack 200 is located. However, while a specific rack 200 has been illustrated and described, one of skill in the art in possession of the present disclosure will recognize that the racks provided in the vertically-mounted side-by-side liquid cooling leak segregation system of the present disclosure may include a variety of components and component configurations while remaining within the scope of the present disclosure as well.

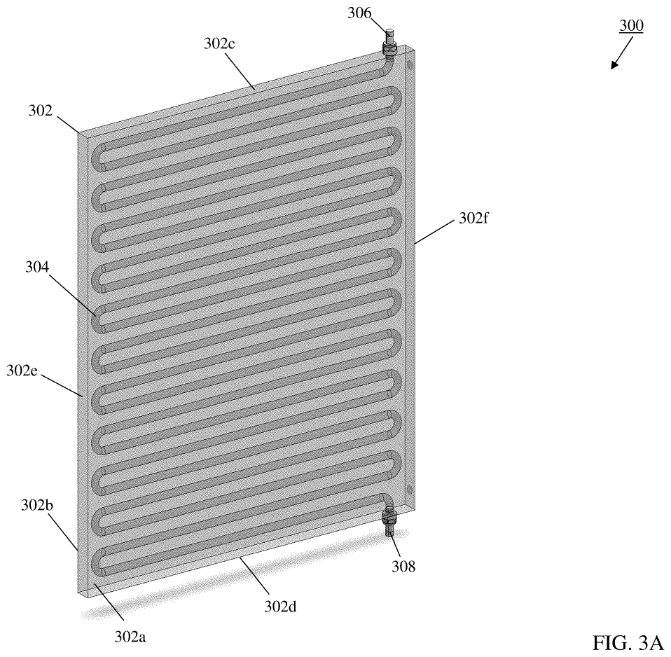

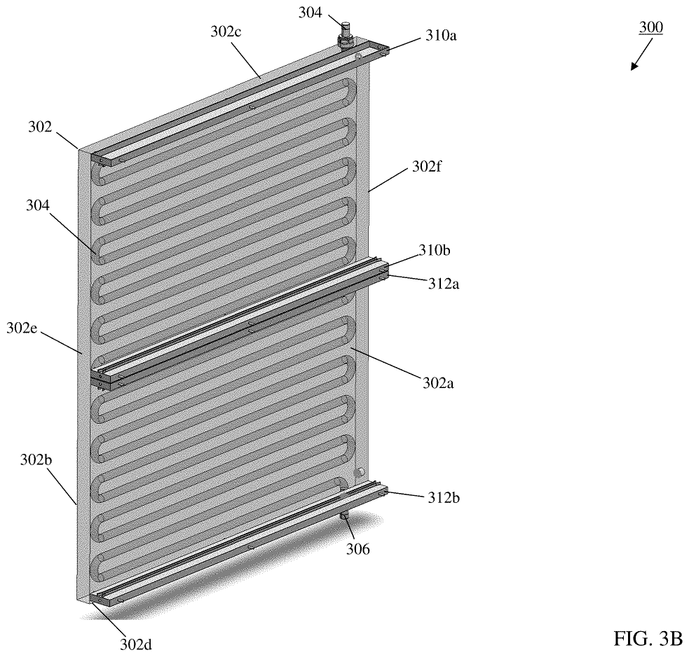

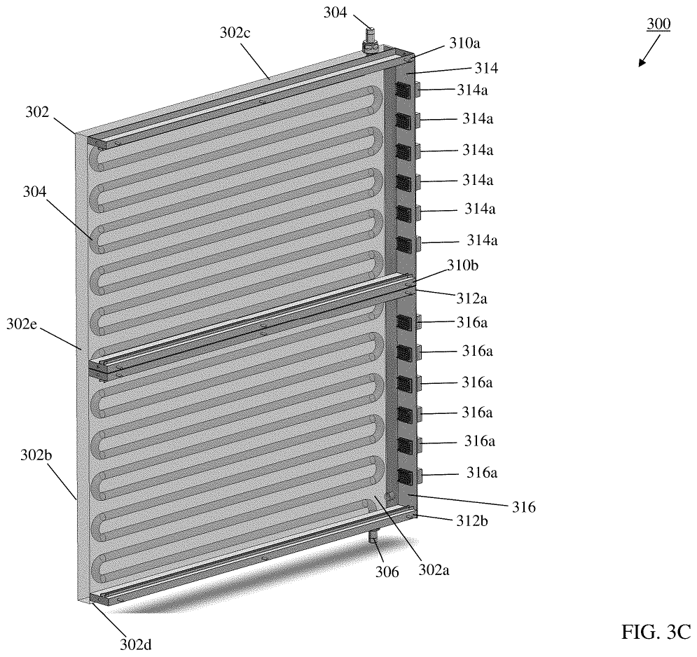

Referring now to FIG. 3A, an embodiment of a liquid cooling device 300 is illustrated that may be included in the vertically-mounted side-by-side liquid cooling leak segregation system of the present disclosure. In the illustrated embodiment, the liquid cooling device 300 includes a chassis 302 that houses or supports the components of the liquid cooling device 300, and that includes a front surface 302a, a rear surface 302b that is located opposite the chassis 302 from the front surface 302a, a top surface 302c that extends between the front surface 302a and the rear surface 302b, a bottom surface 302d that is located opposite the chassis 302 from the top surface 302c and that extends between the front surface 302a and the rear surface 302b, and a pair of side surfaces 302e and 302f that are located opposite the chassis 302 from each other and that extend between the front surface 302a, the rear surface 302b, the top surface 302c, and the bottom surface 302d.

As will be appreciated by one of skill in the art in possession of the present disclosure, the chassis 302 of the liquid cooling device 300 may define a chassis housing between the front surface 302a, the rear surface 302b, the top surface 302c, the bottom surface 302d, and the side surfaces 302e and 302f, and FIG. 3A illustrates the front surface 302a, the rear surface 302b, the top surface 302c, the bottom surface 302d, and the side surfaces 302e and 302f as partially transparent so that the components housed in the chassis housing defined by the chassis 302 of the liquid cooling device 300 can be seen. In the specific examples provided below, a liquid conduit 304 extends through the chassis housing defined by the chassis 302 of the liquid cooling device 300 in a serpentine configuration from a liquid conduit input 306 that extends from the top surface 302c of the chassis 302 adjacent the side surface 302f, and to a liquid conduit output 308 that extends from the bottom surface 302d of the chassis 302 adjacent the side surface 302f. In some examples, the chassis housing defined by the chassis 302 may be hollow and may include drain apertures defined on the bottom surface 302d and/or other features that operate to facilitate the channeling of liquid from any leaks in the liquid conduit 304 through the liquid cooling device 300 and out of the bottom surface 302d as described below.

As will be appreciated by one of skill in the art in possession of the present disclosure and as discussed above, the liquid cooling device 300 in the examples illustrated and described herein is provided by a modular “half-rack-height” liquid cooling device. However, one of skill in the art in possession of the present disclosure will appreciate how the liquid cooling device of the present disclosure may be provided with a variety of other dimensions while remaining within the scope of the present disclosure. Furthermore, while the liquid cooling device 300 is illustrated and described as including a single liquid conduit, additional liquid conduit(s) (each having a corresponding liquid conduit input and output) may be included in the liquid cooling device 300 in order to provide directed cooling for different components cooled via the liquid cooling device 300, multiple cooling levels from the liquid cooling device 300, and/or other liquid cooling features that would be apparent to one of skill in the art in possession of the present disclosure.

With reference to FIG. 3B, the liquid cooling device 300 may be provided with a computing device coupling subsystem that includes a computing device coupling element 310a that extends from the front surface 302a of the chassis 302 of the liquid cooling device 300 between the side surfaces 302e and 302f and immediately adjacent the top surface 302c, and a computing device coupling element 310b that extends from the front surface 302a of the chassis 302 of the liquid cooling device 300 between the side surfaces 302e and 302f and approximately midway between the top surface 302c and the bottom surface 302d, with the computing device coupling elements 310a and 310b including any of a variety of computing device coupling features, securing features, and/or other features that one of skill in the art in possession of the present disclosure would recognize as being configured to couple a computing device to the liquid cooling device 300.

As illustrated, the liquid cooling device 300 may also be provided with a computing device coupling subsystem that includes a computing device coupling element 312a that extends from the front surface 302a of the chassis 302 of the liquid cooling device 300 between the side surfaces 302e and 302f, approximately midway between the top surface 302c and the bottom surface 302d, and immediately adjacent the computing device coupling element 310b, and a computing device coupling element 312b that extends from the front surface 302a of the chassis 302 of the liquid cooling device 300 between the side surfaces 302e and 302f and immediately adjacent the bottom surface 302d, with the computing device coupling elements 312a and 312b including any of a variety of computing device coupling features, securing features, and/or other features that one of skill in the art in possession of the present disclosure would recognize as being configured to couple a computing device to the liquid cooling device 300.

With reference to FIG. 3C, the liquid cooling device 300 may be provided with a computing device connector subsystem 314 that that extends from the side surface 302f of the chassis 302 of the liquid cooling device 300, between the top surface 302c and approximately midway between the top surface 302c and the bottom surface 302d, and between the computing device coupling elements 310a and 310b, and includes a plurality of computing device passthrough connectors 314a. The liquid cooling device 300 may also be provided with a computing device connector subsystem 316 that that extends from the side surface 302f of the chassis 302 of the liquid cooling device 300, between the bottom surface 302d and approximately midway between the top surface 302c and the bottom surface 302d, and between the computing device coupling elements 312a and 312b, and includes a plurality of computing device passthrough connectors 316a. However, while a specific liquid cooling device 300 has been illustrated and described, one of skill in the art in possession of the present disclosure will recognize that liquid cooling devices provided in the vertically-mounted side-by-side liquid cooling leak segregation system of the present disclosure may include a variety of components and configurations that will fall within the scope of the present disclosure as well.

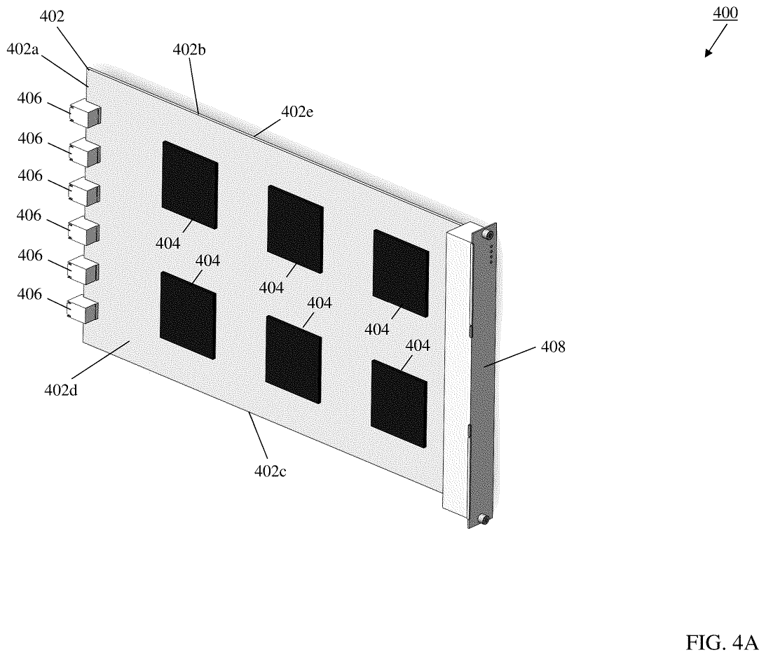

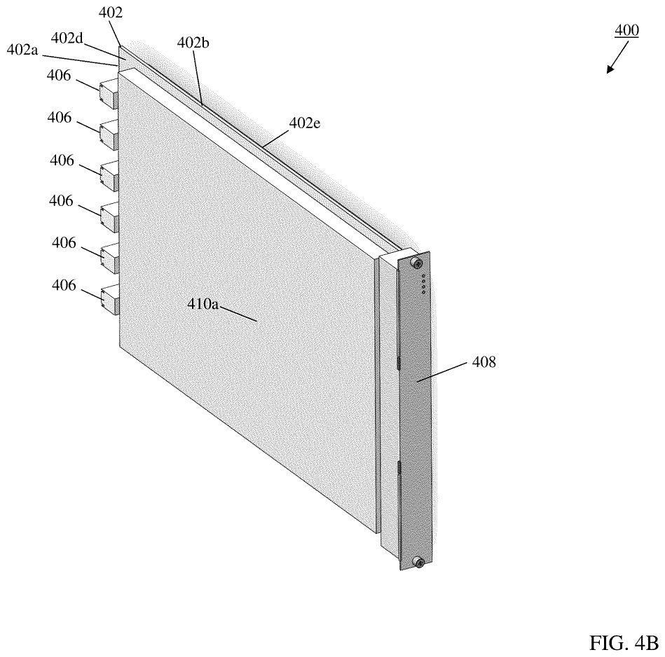

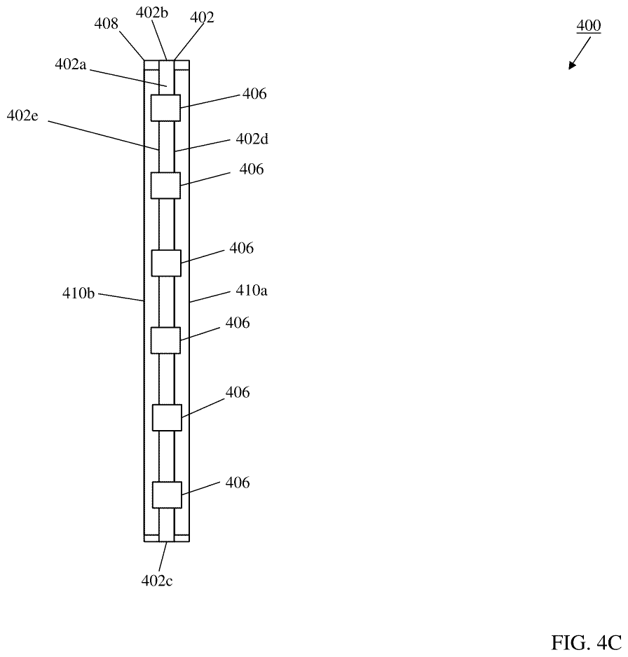

Referring now to FIG. 4A, an embodiment of a computing device 400 is illustrated that may be included in the vertically-mounted side-by-side liquid cooling leak segregation system of the present disclosure. In the illustrated embodiment, the computing device 400 includes a chassis 402 that supports the components of the computing device 400. In the illustrated example, the computing device 400 is provided by a card-type device that includes a circuit board that provides the chassis 402, but one of skill in the art in possession of the present disclosure will appreciate how a variety of computing devices and/or a variety of chassis will fall within the scope of the present disclosure as well. In the illustrated example, the chassis 402 includes a front edge (not visible in FIG. 4A), a rear edge 402a that is located opposite the chassis 402 from the front edge, a top edge 402b that extends between the front edge and the rear edge 402a, a bottom edge 402c that is located opposite the chassis 402 from the top edge 402b and that extends between the front edge and the rear surface 402a, and a pair of side surfaces 402d and 402e that are located opposite the chassis 402 from each other and that extend between the front edge, the rear edge 402a, the top edge 402b, and the bottom edge 402c.

In the illustrated embodiment, a plurality of heat producing components 404 are mounted to the side surface 402d of the chassis 402 of the computing device 400. In the illustrated examples provided below, the heat producing components are provided by six processors, but one of skill in the art in possession of the present disclosure will appreciate how any number and/or types of heat producing components will fall within the scope of the present disclosure. In the illustrated embodiment, a plurality of computing device connectors 406 are provided on the rear edge 402a of the chassis 402 of the computing device 400, and one of skill in the art in possession of the present disclosure will appreciate how the computing device connectors 406 may be coupled to the processors that provide the heat producing components 404 via traces in the circuit board that provides the chassis 402. In the illustrated embodiment, a faceplate 408 extends from the front edge of the chassis 402 opposite the rear edge 402a, and may include any of a variety of rack coupling features, rack securing features, and/or other faceplate features that would be apparent to one of skill in the art in possession of the present disclosure.

With reference to FIGS. 4B and 4C, the computing device 400 may be provided with a heat transfer subsystem that includes a heat sink device 410a that engages the heat producing components 404, and a heat sink device 410b that engages the side surface 402e of the chassis 402. As will be appreciated by one of skill in the art in possession of the present disclosure, the heat sink device 410b may provide a redundant heat sink device (i.e., for situations in which the heat sink device 410a fails), may be provided for addition cooling for the heat producing components 404 (i.e., in addition to the cooling provided by the heat sink device 410a), and/or may be provided for other reasons that would be apparent to one of skill in the art in possession of the present disclosure. As such, the heat sink device 410nb may be omitted in some embodiments (e.g., in embodiments where redundancy or additional cooling are not required for the heat producing components 404). However, while a specific computing device 400 has been illustrated and described, one of skill in the art in possession of the present disclosure will recognize that computing devices provided in the vertically-mounted side-by-side liquid cooling leak segregation system of the present disclosure may include a variety of components and configurations that will fall within the scope of the present disclosure as well.

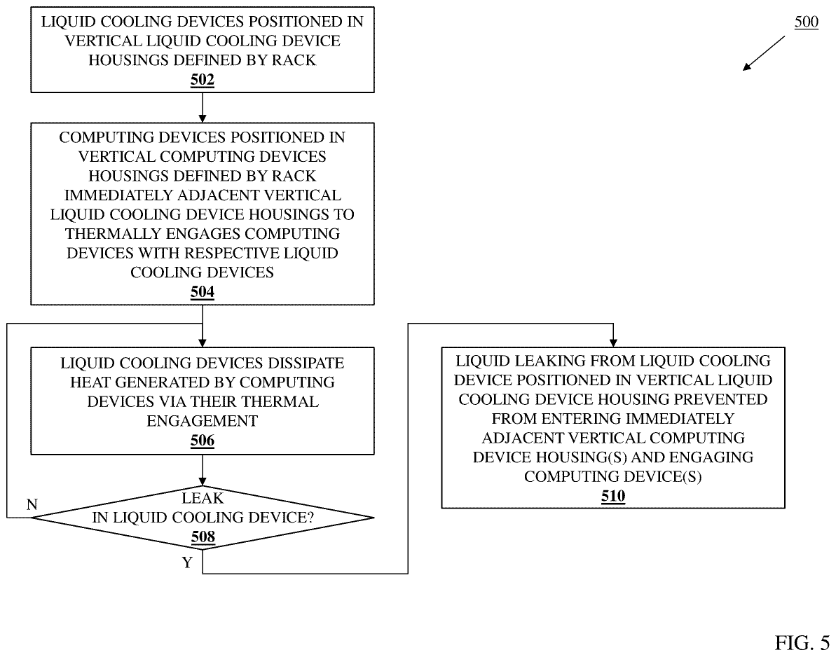

Referring now to FIG. 5, an embodiment of a method 500 for vertically mounting liquid cooling devices side-by-side in a rack with computing devices to segregate leaks illustrated. As discussed below, the systems and methods of the present disclosure provide a rack that defines side-by-side and interleaved/alternating vertical liquid cooling device housings and vertical computing devices housings. For example, the vertically-mounted side-by-side liquid cooling leak segregation system of the present disclosure may include a rack defining a first vertical liquid cooling device housing that is located immediately adjacent a first vertical computing device housing. A first computing device is located in the first vertical computing device housing. A first liquid cooling device is located in the first vertical liquid cooling device housing and thermally engages the first computing device to dissipate heat generated by the first computing device. The first vertical computing device housing and the first vertical liquid cooling device housing position the first computing device side-by-side with the first liquid cooling device to prevent, in response to a first liquid that is circulated through the first liquid cooling device leaking from the first liquid cooling device, the first liquid leaking from the first liquid cooling device from entering the first vertical computing device housing and engaging the first computing device. As such, gravity will operate to prevent any leak in a liquid cooling device positioned in one of the vertical liquid cooling device housings defined by a rack from entering immediately adjacent vertical computing device housing(s) defined by that rack and engaging computing devices positioned therein.

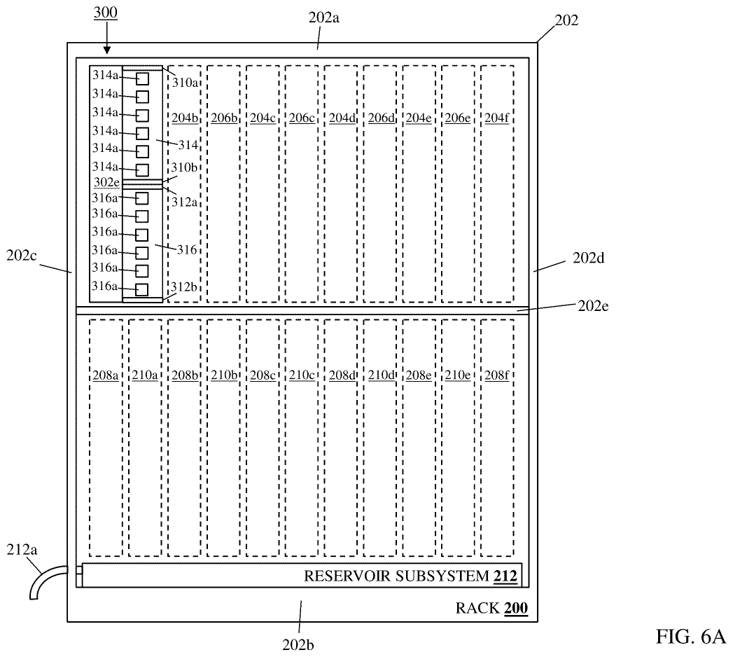

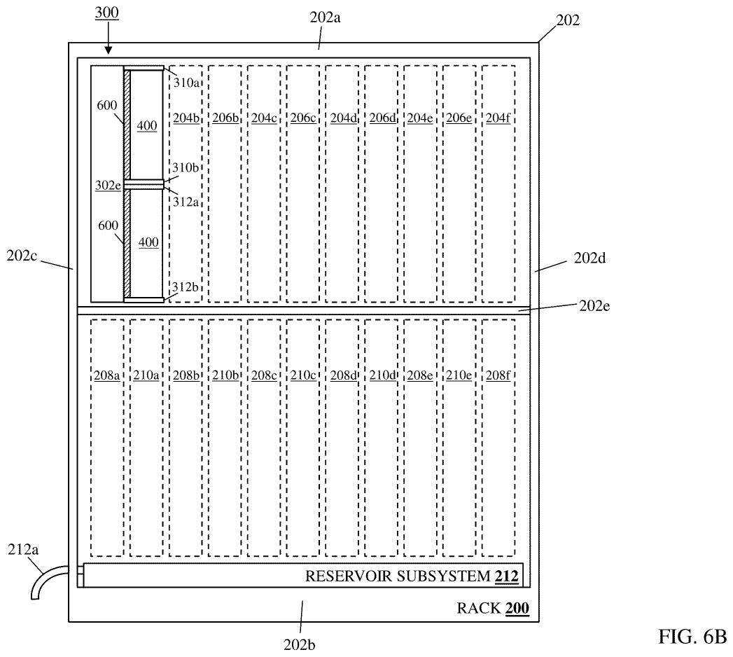

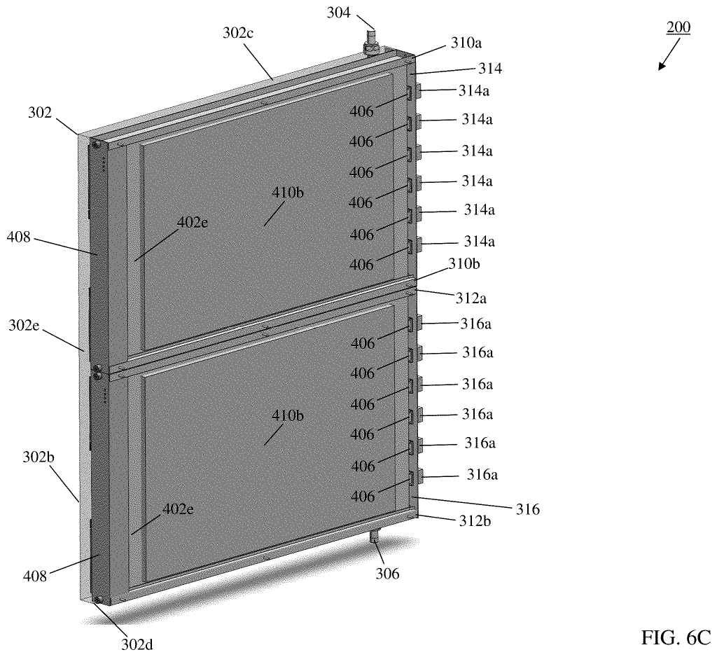

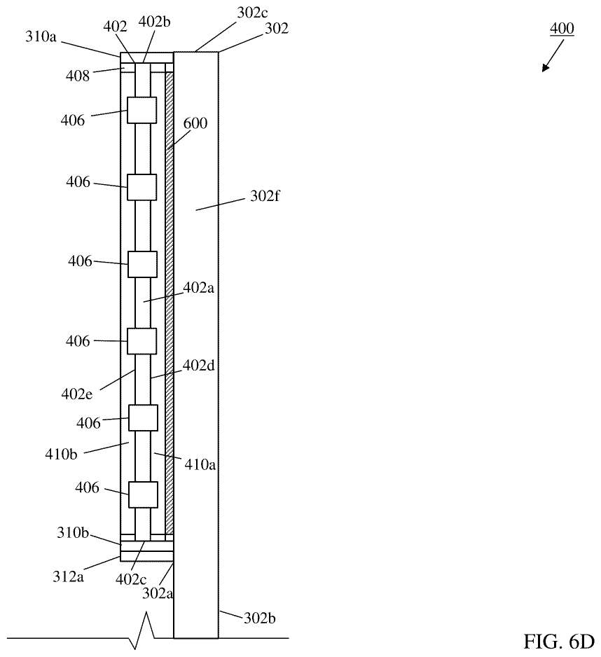

The method 500 begins at block 502 where liquid cooling devices are positioned in vertical liquid cooling device housings defined by a rack. With reference to FIG. 6A, in an embodiment of block 502, one of the liquid cooling devices 300 of FIG. 3C may be positioned in the vertical liquid cooling device housing 204a and coupled/secured to the rack 200 via the liquid cooling device coupling features and securing features that may be included on the top wall 202a, the intermediate wall 202e, and/or the side wall 202c located immediately adjacent the vertical liquid cooling device housing 204a as described above. As can be seen in FIG. 6A, with the liquid cooling device 300 positioned in the vertical liquid cooling device housing 204a, the computing device connector subsystems 314 and 316 extend from the side surface 302f of the chassis 302 of the liquid cooling device 300 and adjacent the vertical computing device housing 206a such that the computing device passthrough connectors 314a and 316a, respectively, are positioned adjacent the vertical computing device housing 206a. Furthermore, with the liquid cooling device 300 positioned in the vertical liquid cooling device housing 204a, the computing device coupling elements 310a/310b and 312a/312b on the computing device coupling subsystems from extend from the front surface 302a of the liquid cooling device 300 and into and/or adjacent the vertical computing device housing 206a.

While not illustrated or described in detail, one of skill in the art in possession of the present disclosure will appreciate how a respective liquid cooling device 300 may be positioned in each of the vertical liquid cooling device housings 204b, 204c, 204d, 204e, 204f, 208a, 208b, 208c, 208d, 208e, and 208f in a substantially similar manner as described above for the liquid cooling device 300 positioned in the vertical liquid cooling device housing 204a, with the exception that the liquid cooling devices 300 positioned in the vertical liquid cooling device housings 204f and 208f may be provided by the liquid cooling device 300 illustrated in FIG. 3A (i.e., one of the liquid cooling devices 300 illustrated in FIG. 3A that does not include the computing device coupling elements 310a/310b and 312a/312b and the computing device connector subsystems 314 and 316 illustrated in FIGS. 3B and 3C may be positioned in each of the vertical liquid cooling device housings 204f and 208f). As such, the computing device coupling elements 310a/310b and 312a/312b and the computing device connector subsystems 314 and 316 on the liquid cooling devices 300 positioned in each of the vertical liquid cooling device housings 204b, 204c, 204d, 204e, 208a, 208b, 208c, 208d, and 208e may extend into and/or adjacent the respective vertical computing device housings 206b, 206c, 206d, 206e, 210a, 210b, 210c, 210d, and 210e.

Furthermore, one of skill in the art in possession of the present disclosure will appreciate how the computing device connector subsystems 314 and 316 on the liquid cooling devices 300 that have been positioned in the rack 200 may be cabled together in any desired manner to provide connectivity for the computing devices 400 that will be connected thereto, allowing computing devices 400 to be connected to and disconnected from those computing device connector subsystems 314 and 316 without the need to decable/recable the rack 200. Further still, one of skill in the art in possession of the present disclosure will appreciate how the cabling of the computing device connector subsystems 314 and 316 on the liquid cooling devices 300 may be as dense as needed due to the liquid cooling eliminating the need to ensure airflow through a wiring matrix provided by that cabling.

The method 500 then proceeds to block 504 where computing devices are positioned in vertical computing device housings defined by the rack immediately adjacent the vertical liquid cooling device housings to thermally engage the computing devices with respective liquid cooling devices. With reference to FIGS. 6B, 6C, and 6D, in an embodiment of block 504, a pair of the computing devices 400 of FIGS. 4B and 4C may be positioned in the vertical computing device housing 206a by coupling a first of those computing devices 400 to the computing device coupling elements 310a/310b on the liquid cooling device 300 positioned in the vertical liquid cooling device housing 204a via the computing device coupling features and/or securing features discussed above (e.g., “sliding” that computing device 400 into a channel provided by those computing device coupling elements 310a/310b and securing that computing device 400 in that channel), and coupling a second of those computing devices 400 to the computing device coupling elements 312a/312b on the liquid cooling device 300 positioned in the vertical liquid cooling device housing 204a via the computing device coupling features and/or securing features discussed above (e.g., “sliding” that computing device 400 into a channel provided by those computing device coupling elements 312a/312b and securing that computing device 400 in that channel).

As can be seen in FIG. 6C, the coupling of the computing device 400 to the computing device coupling elements 310a/310b operates to connect the computing device connectors 406 on that computing device 400 to the computing device passthrough connectors 314a on the computing device connector subsystem 314, and the coupling of the computing device 400 to the computing device coupling elements 312a/312b operates to connect the computing device connectors 406 on that computing device 400 to the computing device passthrough connectors 316a on the computing device connector subsystem 316.

As can be seen in FIGS. 6B and 6D, a respective thermal interface subsystem 600 may be provided between front surface 302a of the liquid cooling device 300 positioned in the vertical liquid cooling device housing 204a and the heat sink device 410a on each of the pair of computing devices 400 positioned in the vertical computing device housing 206a in order to thermally engage those computing devices 400 with that liquid cooling device 300, and one of skill in the art in possession of the present disclosure will appreciate how the thermal interface subsystem 600 may be provided by any of a variety of thermal interface materials, thermal engagement components, and/or other thermal interface elements that one of skill in the art in possession of the present disclosure would recognize as facilitating the transfer of heat generated by the computing devices 400 to the liquid cooling device 300 as described below.

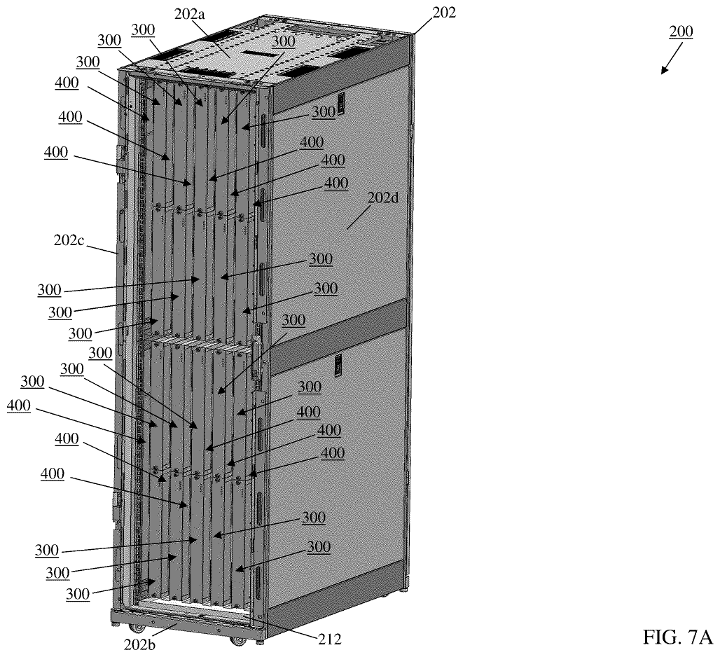

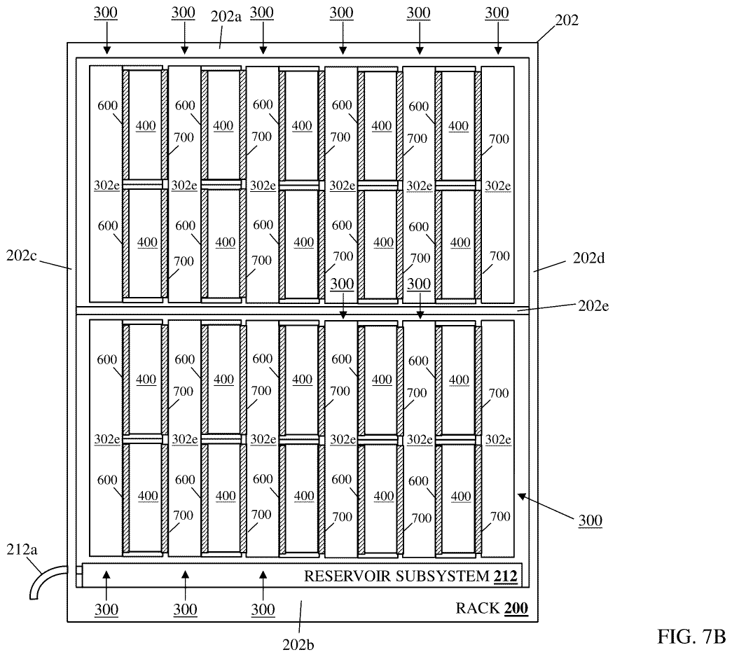

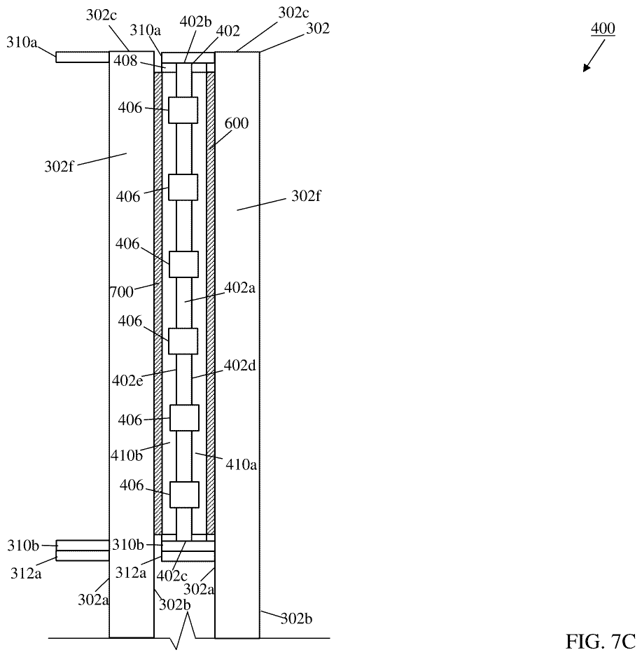

With reference to FIGS. 7A, 7B, and 7C, a respective computing device 400 may be positioned in each of the vertical computing device housings 206b, 206c, 206d, 206e, 210a, 210b, 210c, 210d, and 210e in a substantially similar manner as described above for the computing device 400 positioned in the vertical computing device housing 206a. As such, a computing device 400 may be coupled to the computing device coupling elements 310a/310b on each of the liquid cooling devices 300 that have been housed in the rack 200 such that the computing device connectors 406 on that computing device 400 connect to the computing device passthrough connectors 314a on the computing device connector subsystem 314 on that liquid cooling device 300. Similarly, a computing device 400 may be coupled to the computing device coupling elements 312a/312b on each of the liquid cooling devices 300 that have been housed in the rack 200 such that the computing device connectors 406 on that computing device 400 connect to the computing device passthrough connectors 316a on the computing device connector subsystem 316 on that liquid cooling device 300.

Similarly as described above, a respective thermal interface subsystem 600 may be provided between front surface 302a of the liquid cooling device 300 positioned in each of the vertical liquid cooling device housings 204b, 204c, 204d, 204e, 208a, 208b, 208c, 208d, and 208e and the heat sink device 410a on each of the pair of computing devices 400 positioned in the vertical computing device housing 206b, 206c, 206d, 206e, 210a, 210b, 210c, 210d, and 210e, respectively, in order to thermally engage each of those pairs of computing devices 400 with each of those liquid cooling devices 300, and one of skill in the art in possession of the present disclosure will appreciate how the thermal interface subsystem 600 may be provided by any of a variety of thermal interface materials, thermal engagement components, and/or other thermal interface elements that one of skill in the art in possession of the present disclosure would recognize as facilitating the transfer of heat generated by the computing devices 400 to the liquid cooling devices 300 as described below.

Furthermore, as can be seen in FIGS. 7B and 7C, a respective thermal interface subsystem 700 may be provided between the rear surface 302b of the liquid cooling device 300 positioned in the vertical liquid cooling device housing 204b and the heat sink device 410b on each of the pair of computing devices 400 positioned in the vertical computing device housing 206a in order to thermally engage those computing devices 400 with that liquid cooling device 300, and one of skill in the art in possession of the present disclosure will appreciate how the thermal interface subsystem 700 may be provided by any of a variety of thermal interface materials, thermal engagement components, and/or other thermal interface elements that one of skill in the art in possession of the present disclosure would recognize as facilitating the transfer of heat generated by the computing devices 400 to the liquid cooling device 300 as described below.

Similarly, a respective thermal interface subsystem 700 may be provided between rear surface 302b of the liquid cooling device 300 positioned in each of the vertical liquid cooling device housings 204c, 204d, 204e, 204f, 208b, 208c, 208d, 208e, and 208f and the heat sink device 410b on each of the pair of computing devices 400 positioned in the vertical computing device housing 206a, 206b, 206c, 206d, 206e, 210a, 210b, 210c, 210d, and 210e, respectively, in order to thermally engage each of those pairs of computing devices 400 with each of those liquid cooling devices 300, and one of skill in the art in possession of the present disclosure will appreciate how the thermal interface subsystem 700 may be provided by any of a variety of thermal interface materials, thermal engagement components, and/or other thermal interface elements that one of skill in the art in possession of the present disclosure would recognize as facilitating the transfer of heat generated by the computing devices 400 to the liquid cooling devices 300 as described below.

While the discussion above describes the liquid cooling devices 300 being positioned in the rack 200 prior to the computing devices 400 being coupling to those liquid cooling devices 300 to position those computing devices 400 in the rack 200, one of skill in the art in possession of the present disclosure will appreciate how the computing devices 300 may be coupled to the liquid cooling devices 400 similarly as described above before positioning those liquid cooling devices 400 in the rack 200 similarly as described above (which in turn positions their coupled computing devices 300 in the rack 200) while remaining within the scope of the present disclosure as well.

While not illustrated in detail, one of skill in the art in possession of the present disclosure will appreciate how the liquid conduit input 306 and the liquid conduit output 308 on each of the liquid cooling devices 300 may be coupled to a liquid cooling system that is configured to supply liquid to those liquid cooling devices 300, circulate liquid through those liquid cooling devices 300, remove heat from liquid supplied to and circulated through those liquid cooling devices 300, and/or perform any other liquid cooling operations that would be apparent to one of skill in the art in possession of the present disclosure. To provide a specific example, the liquid cooling device 300 positioned in the vertical liquid cooling device housing 204a may have its liquid conduit input 306 coupled to the liquid cooling system, and may have its liquid conduit output 308 coupled to the liquid conduit input 306 on the liquid cooling device 300 positioned in the vertical liquid cooling device housing 208a, while the liquid conduit output 308 on the liquid cooling device 300 positioned in the vertical liquid cooling device housing 208a may have its liquid conduit output 308 coupled to the liquid cooling system. As will be appreciated by one of skill in the art in possession of the present disclosure, in such an example, the liquid cooling system is configured to circulate liquid through the liquid cooling device 300 positioned in the vertical liquid cooling device housing 204a, and then through the liquid cooling device 300 positioned in the vertical liquid cooling device housing 208a.

Similarly, the liquid cooling devices 300 in the vertical liquid cooling device housings 204b/208b may be coupled to the liquid cooling system and each other, the liquid cooling devices 300 in the vertical liquid cooling device housings 204c/208c may be coupled to the liquid cooling system and each other, the liquid cooling devices 300 in the vertical liquid cooling device housings 204d/208d may be coupled to the liquid cooling system and each other, the liquid cooling devices 300 in the vertical liquid cooling device housings 204e/208e may be coupled to the liquid cooling system and each other, and the liquid cooling devices 300 in the vertical liquid cooling device housings 204f/208f may be coupled to the liquid cooling system and each other substantially as described above for the liquid cooling devices 300 in the vertical liquid cooling device housings 204a/208a. However, while a specific example has been provided in which sets of “vertically stacked” liquid cooling devices are coupled together and to the liquid cooling system (e.g., to enable the independent cooling of corresponding “vertically stacked” computing devices), one of skill in the art in possession of the present disclosure will appreciate how any of a variety of couplings of the liquid cooling devices 300 to each other and to the liquid cooling system will fall within the scope of the present disclosure as well.

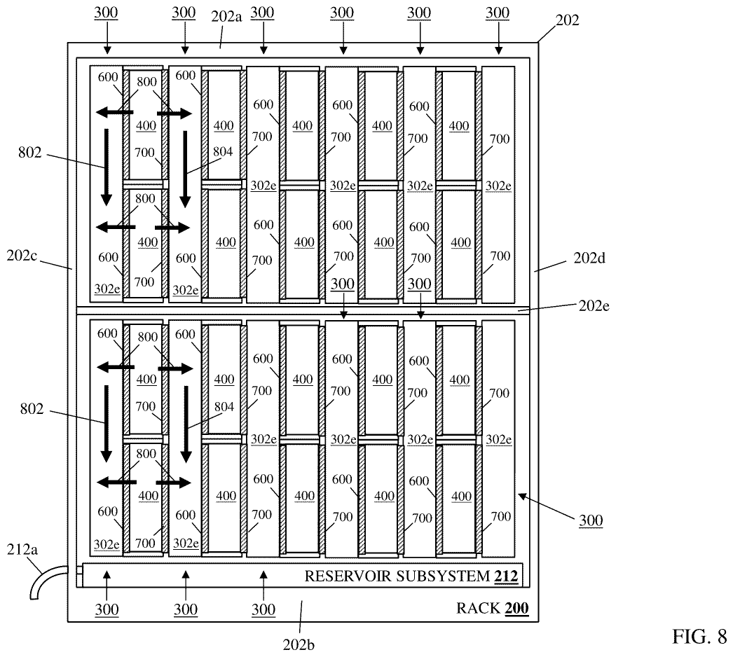

The method 500 then proceeds to block 506 where the liquid cooling devices dissipate heat generated by the computing devices via their thermal engagement. In an embodiment of block 506, each of the computing devices 400 in the rack 200 may operate and, in response, perform heat generation operations that may include the heat producing components 404 on those computing devices 400 generating heat that is transferred via the heat sinks 410a and 410b on that computing device 400 and via the thermal interface subsystems 600 and 700 to the liquid cooling devices 300 that are located on each side of that computing device 400. For example, FIG. 8 illustrates how the computing devices 400 positioned in the vertical computing device housing 206a may operate and, in response, perform heat generation operations 800 that include generating heat that is transferred via the heat sinks 410a and 410b on those computing device 400 and via the thermal interface subsystems 600 and 700 to the liquid cooling devices 300 that are located on each side of those computing devices 400 and positioned in the vertical liquid cooling device housings 204a and 204b, as well as how the computing devices 400 positioned in the vertical computing device housing 210a may operate and, in response perform heat generation operations 800 that include the heat producing components 404 on those computing devices 400 generating heat that is transferred via the heat sinks 410a and 410b on those computing device 400 and via the thermal interface subsystems 600 and 700 to the liquid cooling devices 300 that are located on each side of those computing devices 400 and positioned in the vertical liquid cooling device housings 208a and 208b.

FIG. 8 also illustrates how the liquid cooling devices 300 positioned in the vertical liquid cooling device housings 204a and 208a may perform heat dissipation operations 802 that include dissipating the heat generated by the computing devices 300 positioned in the vertical computing devices housings 206a and 210a. As will be appreciated by one of skill in the art in possession of the present disclosure, at block 506 the liquid cooling system coupled to the liquid cooling devices 300 positioned in the vertical liquid cooling device housings 204a and 208a may operate to supply and circulate a liquid through the liquid cooling devices 300 positioned in the vertical liquid cooling device housings 204a and 208a (e.g., by pumping that liquid from a liquid reservoir and through the liquid conduit inlet 304 on the liquid cooling device 300 positioned in the vertical liquid cooling device housing 204a such that the liquid flows through the liquid conduit 304 in the liquid cooling device 300 positioned in the vertical liquid cooling device housing 204a, out of the liquid conduit outlet 306 on the liquid cooling device 300 positioned in the vertical liquid cooling device housing 204a, into the liquid conduit inlet 304 on the liquid cooling device 300 positioned in the vertical liquid cooling device housing 208a such that the liquid flows through the liquid conduit 304 in the liquid cooling device 300 positioned in the vertical liquid cooling device housing 208a, out of the liquid conduit outlet 306 on the liquid cooling device 300 positioned in the vertical liquid cooling device housing 208a, and back to the liquid reservoir in the liquid cooling system).

Similarly, FIG. 8 also illustrates how the liquid cooling devices 300 positioned in the vertical liquid cooling device housings 204b and 208b may perform heat dissipation operations 804 that include dissipating the heat generated by the computing devices 300 positioned in the vertical computing devices housings 206a and 210a. As will be appreciated by one of skill in the art in possession of the present disclosure, at block 506 the liquid cooling system coupled to the liquid cooling devices 300 positioned in the vertical liquid cooling device housings 204b and 208b may operate to supply and circulate a liquid through the liquid cooling devices 300 positioned in the vertical liquid cooling device housings 204b and 208b (e.g., by pumping that liquid from a liquid reservoir and through the liquid conduit inlet 304 on the liquid cooling device 300 positioned in the vertical liquid cooling device housing 204b such that the liquid flows through the liquid conduit 304 in the liquid cooling device 300 positioned in the vertical liquid cooling device housing 204b, out of the liquid conduit outlet 306 on the liquid cooling device 300 positioned in the vertical liquid cooling device housing 204b, into the liquid conduit inlet 304 on the liquid cooling device 300 positioned in the vertical liquid cooling device housing 208b such that the liquid flows through the liquid conduit 304 in the liquid cooling device 300 positioned in the vertical liquid cooling device housing 208b, out of the liquid conduit outlet 306 on the liquid cooling device 300 positioned in the vertical liquid cooling device housing 208b, and back to the liquid reservoir in the liquid cooling system).

As will be appreciated by one of skill in the art in possession of the present disclosure, the supply and circulation of liquid through the liquid cooling devices 300 positioned in the vertical liquid cooling device housings 204a/208a and 204b/208b (as well as the cooling of that liquid prior to supplying it to those liquid cooling devices 300) will operate to dissipate the heat generated as part of the heat generation operations 800 discussed above by transferring that heat to the liquid that is supplied and circulated through those liquid cooling devices 300 and then cooling that liquid at the liquid cooling system. Furthermore, while the heat dissipation operations are illustrated and described as being performed by the liquid cooling devices 300 that thermally engage opposing sides of any particular computing device 400, as discussed above, the thermal engagement of the computing devices 400 on opposing sides with liquid cooling devices 300 may be for redundancy purposes, and thus the heat dissipation operations described above may only be performed by liquid cooling devices 300 thermally engaging one side of the computing devices 400 while remaining within the scope of the present disclosure as well.

Furthermore, as described above, the liquid cooling devices of the present disclosure may be provided with more than one liquid conduit, each having a corresponding liquid conduit input and output, in order to provide directed cooling for components cooled via the liquid cooling device 300 and/or different cooling levels from the liquid cooling device 300, and thus the directed cooling of particular heat producing components 404 on the computing devices 400 and/or provisioning of different cooling levels for the heat producing components 404 on the computing devices 400 at block 506 will fall within the scope of the present disclosure as well.

The method 500 then proceeds to decision block 508 where the method 508 proceeds depending on whether a leak occurs in a liquid cooling device. As will be appreciated by one of skill in the art in possession of the present disclosure, any of the liquid cooling devices 300 may degrade, get damaged, and/or otherwise be compromised such that the liquid being supplied and circulated through that liquid cooling device 300 by the liquid cooling system begins to leak from that liquid cooling device. If, at decision block 506, no leak occurs in a liquid cooling device, the method 500 returns to block 506. As such, the method 500 may loop such that the liquid cooling devices 300 continue to dissipate heat generated by the computing devices 400 via their thermal engagement until a leak occurs any of those liquid cooling devices 300.

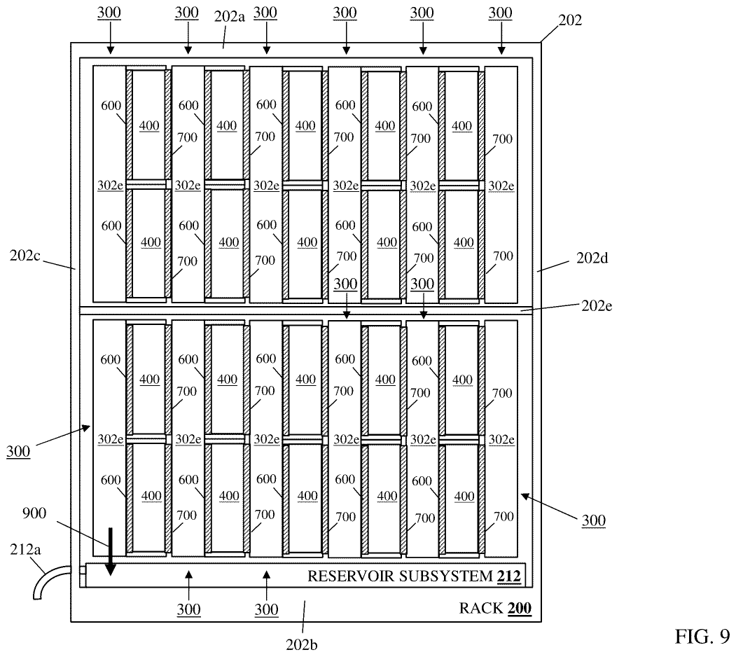

If, at decision block 506, a leak occurs in a liquid cooling device, the method 500 proceeds to block 510 where liquid leaking from the liquid cooling device positioned in a vertical liquid cooling device housing is prevented from entering the immediately adjacent vertical computing device housing(s) and engaging the computing device(s) positioned in those vertical computing device housing(s). With reference to FIG. 9, in an embodiment of block 510, a leak may occur in either of the liquid cooling devices 300 positioned in the vertical liquid cooling device housings 204a and 208a and, in response, the vertically-mounted side-by-side liquid cooling leak segregation system of the present disclosure may perform leak segregation operations 900 that prevent the liquid escaping that liquid cooling device(s) 300 via that leak from entering the immediately adjacent vertical computing device housings 206a and 210a and engaging the computing devices 400 positioned therein, and channel that liquid to the reservoir subsystem 212 such that it may be stored therein. Furthermore, in the event the amount of liquid in the reservoir subsystem 212 reaches a maximum level, that liquid may be drained away from the chassis 212 via the emergency drain element 212a as described above. In some embodiments, the reservoir subsystem 212 may include liquid detection sensors and/or other alert subsystems to alert a network administrator or other user when liquid is collected in the reservoir subsystem 212.

As will be appreciated by one of skill in the art in possession of the present disclosure, the “vertical stacking” of the vertical liquid cooling device housings and the “side-by-side” orientation of the “vertically stacked” vertical liquid cooling device housings and “vertically stacked” vertical computing device housings (e.g., the vertically stacked vertical liquid cooling device housings 204a/208a that are side-by-side with the vertically stacked vertical computing device housings 206a/210a, which are side-by-side with the vertically stacked vertical liquid cooling device housings 204b/208b, which are side-by-side with the vertically stacked vertical computing device housings 206b/210b, and so on) allow gravity to channel the liquid leaking from any liquid cooling device 300 that is positioned one of the vertically stacked vertical liquid cooling device housings through those vertically stacked vertical liquid cooling device housings and to the reservoir system 212 such that liquid does not enter the immediately adjacent, vertically stacked computing device housings and engage the computing devices 400 positioned therein.

Furthermore, the thermal engagement subsystems 600 and 700 may be configured to prevent any liquid leaking from a liquid cooling device 300 under pressure from spraying into an immediately adjacent, vertically stacked computing device housing and engaging the computing devices 400 positioned therein. As such, liquid escaping any liquid cooling device 300 in the rack 200 via leak will be segregated to the vertically stacked vertical liquid cooling device housings and channeled to the reservoir subsystem 212, eliminating the issues with conventional liquid cooling systems where the positioning of liquid cooling devices on top of and in contact with computing devices in racks presents the risk of liquid escaping from leaks occurring in those liquid cooling systems engaging those computing devices.

Furthermore, one of skill in the art in possession of the present disclosure will appreciate how the vertically-mounted side-by-side liquid cooling leak segregation system of the present disclosure enables increased computing device density and more optical rack space usage due to the enhance cooling provided by the liquid cooling devices, allowing the computing devices to be positioned relatively closely together with relatively lower interconnect reach requirements, as well as reducing power usage, costs, and/or providing other benefits that would be apparent to one of skill in the art in possession of the present disclosure.

Thus, systems and methods have been described that provide a rack that defines side-by-side and interleaved/alternating vertical liquid cooling device housings and vertical computing devices housings. For example, the vertically-mounted side-by-side liquid cooling leak segregation system of the present disclosure may include a rack defining a first vertical liquid cooling device housing that is located immediately adjacent a first vertical computing device housing. A first computing device is located in the first vertical computing device housing. A first liquid cooling device is located in the first vertical liquid cooling device housing and thermally engages the first computing device to dissipate heat generated by the first computing device. The first vertical computing device housing and the first vertical liquid cooling device housing position the first computing device side-by-side with the first liquid cooling device to prevent, in response to a first liquid that is circulated through the first liquid cooling device leaking from the first liquid cooling device, the first liquid leaking from the first liquid cooling device from entering the first vertical computing device housing and engaging the first computing device. As such, gravity will operate to prevent any leak in a liquid cooling device positioned in one of the vertical liquid cooling device housings defined by a rack from entering immediately adjacent vertical computing device housing(s) defined by that rack and engaging computing devices positioned therein.

Although illustrative embodiments have been shown and described, a wide range of modification, change and substitution is contemplated in the foregoing disclosure and in some instances, some features of the embodiments may be employed without a corresponding use of other features. Accordingly, it is appropriate that the appended claims be construed broadly and in a manner consistent with the scope of the embodiments disclosed herein.

What is claimed is:

1. A vertically-mounted side-by-side liquid cooling leak segregation system, comprising:
a rack defining:
a first vertical liquid cooling device housing; and
a first vertical computing device housing that is located immediately adjacent the first vertical liquid cooling device housing;
a first computing device that is located in the first vertical computing device housing; and
a first liquid cooling device that is located in the first vertical liquid cooling device housing and that thermally engages the first computing device to dissipate heat generated by the first computing device, wherein the first vertical computing device housing and the first vertical liquid cooling device housing position the first computing device side-by-side with the first liquid cooling device to prevent, in response to a first liquid that is circulated through the first liquid cooling device leaking from the first liquid cooling device, the first liquid leaking from the first liquid cooling device from entering the first vertical computing device housing and engaging the first computing device.

2. The system of claim 1, further comprising:
a second vertical liquid cooling device housing that is located immediately adjacent the first vertical computing device housing and opposite the first vertical computing device housing from the first vertical liquid cooling device housing; and
a second liquid cooling device that is located in the second vertical liquid cooling device housing and that thermally engages the first computing device to dissipate heat generated by the first computing device, wherein the first vertical computing device housing and the second vertical liquid cooling device housing position the first computing device side-by-side with the second liquid cooling device to prevent, in response to a second liquid that is circulated through the second liquid cooling device leaking from the second liquid cooling device, the second liquid leaking from the second liquid cooling device from entering the first vertical computing device housing and engaging the first computing device.

3. The system of claim 1, further comprising:
a reservoir subsystem that is included in the rack and that is configured, in response to the first liquid that is circulated through the first liquid cooling device leaking from the first liquid cooling device, to receive the first liquid leaking from the first liquid cooling device.

4. The system of claim 1, further comprising:
a first computing device coupling subsystem that extends from the first liquid cooling device, wherein the first computing device is connected to the first computing device coupling subsystem to locate the first computing device in the first vertical computing device housing and to thermally engage the first computing device and the first liquid cooling device.

5. The system of claim 1, further comprising:
a first computing device connector subsystem that extends from the first liquid cooling device, wherein the first computing device is connected to the first computing device connector subsystem.

6. The system of claim 1, further comprising:
a thermal interface subsystem that is located between the first liquid cooling device and the first computing device and that thermally engages the first liquid cooling device and the first computing device.

7. A rack, comprising:
a rack chassis;
a plurality of vertical liquid cooling device housings that are defined by the rack chassis and that are each configured to house a respective liquid cooling device; and
a plurality of vertical computing device housings that are defined by the rack chassis such that a respective one of the plurality of vertical computing device housings is located immediately adjacent a respective one of the plurality of vertical liquid cooling device housings, wherein each of the plurality of vertical computing device housings is configured to house a respective computing device, and
wherein the plurality of vertical liquid cooling device housings and the plurality of vertical computing device housings are configured to position the respective computing device housed in any of the plurality of vertical computing device housings side-by-side and in thermal engagement with the respective liquid cooling device housed in one of the plurality of vertical liquid cooling device housings that is located immediately adjacent that vertical computing device housing to prevent, in response to a liquid that is circulated through that respective liquid cooling device leaking from that respective liquid cooling device, the liquid leaking from that respective liquid cooling device from entering that vertical computing device housing and engaging that respective computing device.

8. The rack of claim 7, wherein the plurality of vertical liquid cooling device housings and the plurality of vertical computing device housings are configured to position a first computing device housed in a first vertical computing housing that is included in the plurality of vertical computing device housings side-by-side and in thermal engagement with:
a first liquid cooling device housed in a first vertical liquid cooling device housing that is included in the plurality of vertical liquid cooling device housings and that is located immediately adjacent the first vertical computing device housing; and
a second liquid cooling device housed in a second vertical liquid cooling device housing that is included in the plurality of vertical liquid cooling device housings and that is located immediately adjacent the first vertical computing device housing.

9. The rack of claim 7, further comprising:
a reservoir subsystem that is included in the rack chassis and that is configured, in response to a liquid that is circulated through the respective liquid cooling device housed in any of the plurality of vertical liquid cooling device housings leaking from that respective liquid cooling device, to receive the liquid leaking from that respective liquid cooling device.

10. The rack of claim 7, further comprising:
a first liquid cooling device housed in a first vertical liquid cooling device housing that is included in the plurality of vertical liquid cooling device housings; and
a first computing device housed in a first computing device housing that is included in the plurality of vertical computing device housings and that is located immediately adjacent the first liquid cooling device housing.

11. The rack of claim 10, further comprising:
a first computing device coupling subsystem that extends from the first liquid cooling device, wherein the first computing device is connected to the first computing device coupling subsystem to locate the first computing device in the first vertical computing device housing and to thermally engage the first computing device and the first liquid cooling device.

12. The rack of claim 10, further comprising:
a first computing device connector subsystem that extends from the first liquid cooling device, wherein the first computing device is connected to the first computing device connector subsystem.

13. The rack of claim 10, further comprising:
a thermal interface subsystem that is located between the first liquid cooling device and the first computing device and that thermally engages the first liquid cooling device and the first computing device.

14. A method for vertically mounting liquid cooling devices side-by-side in a rack with computing devices to segregate leaks, comprising:
receiving, by a first vertical liquid cooling device housing that is defined by a rack, a first liquid cooling device;
receiving, by a first vertical computing device housing that is defined by the rack and located immediately adjacent the first vertical liquid cooling device housing, a first computing device such that the first computing device thermally engages the first liquid cooling device;
dissipating, by the first liquid cooling device via the thermal engagement with the first computing device, heat generated by the first computing device; and
preventing, via the positioning of the first computing device in the first vertical computing device housing side-by-side with the first liquid cooling device in the first vertical liquid cooling device housing and in response to a first liquid that is circulated through the first liquid cooling device leaking from the first liquid cooling device, the first liquid leaking from the first liquid cooling device from entering the first vertical computing device housing and engaging the first computing device.

15. The method of claim 14, further comprising:
receiving, by a second vertical liquid cooling device housing that is defined by the rack and located immediately adjacent the first vertical computing device housing and opposite the first vertical computing device housing from the first vertical liquid cooling device housing, a second liquid cooling device such that the first computing device thermally engages the second liquid cooling device; and
dissipating, by the second liquid cooling device via the thermal engagement with the first computing device, the heat generated by the first computing device; and
preventing, via the positioning of the first computing device in the first vertical computing device housing side-by-side with the second liquid cooling device in the second vertical liquid cooling device housing and in response to a second liquid that is circulated through the second liquid cooling device leaking from the second liquid cooling device, the second liquid leaking from the second liquid cooling device from entering the first vertical computing device housing and engaging the first computing device.

16. The method of claim 14, further comprising:
receiving, by a reservoir subsystem that is included in the rack and in response to the first liquid that is circulated through the first liquid cooling device leaking from the first liquid cooling device, the first liquid leaking from the first liquid cooling device.

17. The method of claim 14, further comprising:
connecting, by the first computing device, to a first computing device coupling subsystem that extends from the first liquid cooling device to locate the first computing device in the first vertical computing device housing and to thermally engage the first computing device and the first liquid cooling device.

18. The method of claim 14, further comprising:
connecting, by the first computing device, to a first computing device connector subsystem that extends from the first liquid cooling device.

19. The method of claim 14, further comprising:
thermally engaging, by a thermal interface subsystem that is located between the first liquid cooling device and the first computing device, the first liquid cooling device and the first computing device.

20. The method of claim 14, wherein the preventing, in response to the first liquid that is circulated through the first liquid cooling device leaking from the first liquid cooling device, the first liquid leaking from the first liquid cooling device from entering the first vertical computing device housing and engaging the first computing device is performed based on a combination of gravity and the positioning of the first computing device in the first vertical computing device housing side-by-side with the first liquid cooling device in the first vertical liquid cooling device housing.
